(19) United States
(12) Patent Application Publication
(10) Pub. No.: US 2020/0303544 A1
(43) Pub. Date: Sep. 24, 2020

(54) SEMICONDUCTOR DEVICE AND METHOD FOR FABRICATING THE SAME

(71) Applicant: Samsung Electronics Co., Ltd., Suwon-si (KR)

(72) Inventors: Min Chong PARK, Seongnam-si (KR); Jun Gu Kang, Hwaseong-si (KR); Yong Sang Jeong, Hwaseong-si (KR)

(73) Assignee: Samsung Electronics Co., Ltd., Suwon-si (KR)

(21) Appl. No.: 16/533,073

(22) Filed: Aug. 6, 2019

(30) Foreign Application Priority Data
Mar. 20, 2019 (KR) 10-2019-0031526

(51) Int. Cl. H01L 29/78; H01L 21/762; H01L 29/06

(52) U.S. Cl. CPC H01L 29/7833; H01L 29/0607; H01L 21/76237

(57) ABSTRACT

A semiconductor device is provided. The semiconductor device comprises a substrate, a gate electrode on the substrate, an element isolation film in the substrate and spaced apart from the gate electrode, an impurity region between the element isolation film and the gate electrode, the impurity region including a first impurity of a first concentration, and a depletion buffer region on at least a part of side walls of the element isolation film, the depletion buffer region including a second impurity of a second concentration higher than the first concentration, a conductivity type of the second impurity being the same as a conductivity type of the first impurity.

### CROSS-REFERENCE TO RELATED APPLICATION

This application claims priority from Korean Patent Application No. 10-2019-0031526 filed on Mar. 20, 2019 in the Korean Intellectual Property Office, and all the benefits accruing therefrom under 35 U.S.C. 119, the contents of which in its entirety are herein incorporated by reference.

### BACKGROUND

### 1. Field of the Invention

The present inventive concepts relate to a semiconductor device and a method for fabricating the same.

### 2. Description of the Related Art

As semiconductor elements are highly integrated, the size of MOSFET (Metal Oxide Semiconductor Field Effect Transistor) constituting a semiconductor memory element is also reduced to improve the integration and speed. However, the reduction in size of the MOSFET may induce a short channel effect.

In particular, a junction depletion of a source/drain region may approach a silicon surface. For example, a distance between a silicide on the silicon surface and the junction depletion of a drain region decreases, and isolation breakdown voltage characteristics may deteriorate. Thus, a doping concentration of the source/drain region may be increased so that the junction depletion of the source/drain region is separated from the silicon surface.

### SUMMARY

Some example embodiments of the present inventive concepts provide a semiconductor device with improved reliability.

Some example embodiments of the present inventive concepts also provide a method for fabricating a semiconductor device with improved reliability.

According to some example embodiments of the present inventive concepts, there is provided a semiconductor device comprising a substrate, a gate electrode on the substrate, an element isolation film in the substrate and spaced apart from the gate electrode, an impurity region between the element isolation film and the gate electrode, the impurity region including a first impurity of a first concentration, and a depletion buffer region on at least a part of side walls of the element isolation film, the depletion buffer region including a second impurity of a second concentration higher than the first concentration, a conductivity type of the second impurity being the same as a conductivity type of the first impurity.

According to some example embodiments of the present inventive concepts, there is provided a semiconductor device comprising a substrate, first and second element isolation films in the substrate, a gate electrode on the substrate between the first element isolation film and the second element isolation film, a first impurity region between the first element isolation film and the gate electrode, the first impurity region including a first impurity of a first concentration, a second impurity region between the second element isolation film and the gate electrode, the second impurity region including a second impurity of a second concentration, and a depletion buffer region on at least a part of side walls of the second element isolation film and including a third impurity of a third concentration higher than the second concentration, a conductivity type of the third impurity being the same as the conductivity type of the second impurity.

According to some example embodiments of the present inventive concepts, there is provided a semiconductor device comprising a substrate a gate electrode on the substrate, an element isolation film in the substrate and spaced apart from the gate electrode, a first impurity region including a first impurity of a first concentration between the element isolation film and the gate electrode, a second impurity region including a second impurity of a second concentration higher than the first concentration, between the first impurity region and the element isolation film, a conductivity type of the second impurity being the same as the conductivity type of the first impurity, and a depletion buffer region on at least a part of side walls of the element isolation film and including a third impurity of a third concentration higher than the second concentration, a conductivity type of the third impurity being the same as that of the second impurity.

However, embodiments of the present inventive concepts are not restricted to the one set forth herein. The above and other embodiments of the present inventive concepts will become more apparent to one of ordinary skill in the art to which the present inventive concepts pertain by referencing the detailed description of the present inventive concepts given below.

### BRIEF DESCRIPTION OF THE DRAWINGS

The above and other embodiments and features of the present inventive concepts will become more apparent by describing in detail example embodiments thereof with reference to the attached drawings, in which:

FIG. 1 is an example view of a semiconductor device.

FIG. 2A is an enlarged view of the junction A of the semiconductor device of FIG. 1.

FIG. 2B is an enlarged view of a junction A of the semiconductor device of FIG. 1.

FIG. 3 is an example diagram of the semiconductor device according to some example embodiments of the present inventive concepts.

FIG. 4 is an enlarged view of a junction A of the semiconductor device according to some example embodiments of the present inventive concepts.

FIG. 5 is an intermediate stage view illustrating a method for fabricating the semiconductor device of FIG. 3 according to some example embodiments of the present inventive concepts.

FIG. 6 is an intermediate stage view illustrating the method for fabricating the semiconductor device of FIG. 3 according to some example embodiments of the present inventive concepts.

FIG. 7 is an intermediate stage view illustrating the method for fabricating the semiconductor device of FIG. 3 according to some example embodiments of the present inventive concepts.

FIG. 8 is an intermediate stage view illustrating the method for fabricating the semiconductor device of FIG. 3 according to some example embodiments of the present inventive concepts.

FIG. 9 is an intermediate stage view illustrating the method for fabricating the semiconductor device of FIG. 3 according to some example embodiments of the present inventive concepts.

FIG. 10 is an intermediate stage view illustrating the method for fabricating the semiconductor device of FIG. 3 according to some example embodiments of the present inventive concepts.

FIG. 11 is an intermediate stage view illustrating the method for fabricating the semiconductor device of FIG. 3 according to some example embodiments of the present inventive concepts.

FIG. 12 is an intermediate stage view illustrating the method for fabricating the semiconductor device of FIG. 3 according to some example embodiments of the present inventive concepts.

FIG. 13 is an example diagram of the semiconductor device according to some example embodiments of the present inventive concepts.

FIG. 14 is an intermediate stage view illustrating the method for fabricating the semiconductor device of FIG. 13 according to some example embodiments of the present inventive concepts.

FIG. 15 is an intermediate stage view illustrating the method for fabricating the semiconductor device of FIG. 13 according to some example embodiments of the present inventive concepts.

FIG. 16 is an intermediate stage view illustrating the method for fabricating the semiconductor device of FIG. 13 according to some example embodiments of the present inventive concepts.

FIG. 17 is an intermediate stage view illustrating the method for fabricating the semiconductor device of FIG. 13 according to some example embodiments of the present inventive concepts.

### DETAILED DESCRIPTION

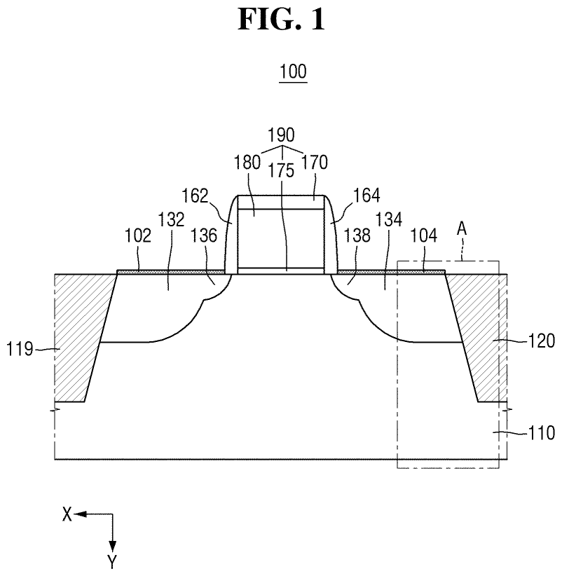

FIG. 1 is an example view of a semiconductor device.

Although the drawings relating to a semiconductor device and a method for fabricating the semiconductor device according to some example embodiments of the present inventive concepts illustrate a method for forming a planar transistor, the present inventive concepts are not limited thereto. The semiconductor device and the method for fabricating the semiconductor device according to some example embodiments of the present inventive concepts may be used in the semiconductor device having various structures such as a buried channel array transistor (BCAT) or a recess channel array transistor (RCAT).

In addition, a semiconductor device fabricated using the method for fabricating the semiconductor device according to some example embodiments of the present inventive concepts may include a bipolar junction transistor, a lateral double diffusion transistor (LDMOS), and the like.

Referring to FIG. 1, a gate insulating film 175, a gate electrode 180, and/or a gate hard mask 170 sequentially stacked on a substrate 110 of a semiconductor device 100 may be formed. In addition, a first spacer film 162 and/or a second spacer film 164 may be formed on side walls of the gate electrode 180. The gate insulating film 175, the gate electrode 180, and/or the gate hard mask 170 may form a gate stack 190. A first element isolation film 119 and a second element isolation film 120 may be formed on respective sides of the substrate 110. A first low-concentration impurity region 136 and/or a first impurity region 132 may be formed between the gate stack 190 and the first element isolation film 119. A first metal silicide film 102 may be formed on the first low-concentration impurity region 136 and/or the first impurity region 132. A second low-concentration impurity region 138 and/or a second impurity region 134 may be formed between the gate stack 190 and the second element isolation film 120. A second metal silicide film 104 may be formed on the second low-concentration impurity region 138 and/or the second impurity region 134.

More specifically, the first element isolation film 119 and/or the second element isolation film 120 may be formed in the substrate 110. The first element isolation film 119 and/or the second element isolation film 120 may be formed as a shallow trench isolation (STI) structure that is advantageous for a high integration because of excellent element isolation characteristics and a small occupied area, but the inventive concepts are not limited thereto.

The first element isolation film 119 and the second element isolation film 120 may include, for example, one of silicon oxide, silicon oxynitride, silicon nitride, and combinations thereof.

A first spacer film 162 and/or a second spacer film 164 for covering the gate stack 190 may be formed on the substrate 110. By directionally etching the first spacer film 162 and/or the second spacer film 164, the first spacer film 162 and/or the second spacer film 164 may be formed on the side walls of the gate stack 190.

The substrate 110 may be bulk silicon or silicon-on-insulator (SOI). Alternatively, the substrate 110 may be a silicon substrate or may include, but is not limited to, other materials, for example, silicon germanium, SGOI (Silicon Germanium On Insulator), indium antimonide, lead tellurium compound, indium arsenide, phosphide indium, gallium arsenide, gallium antimonide, and combinations thereof. In the following description, the substrate 110 will be described as a silicon substrate.

The gate insulating film 175 may be, for example, a silicon oxide film, SiON, GexOyNz, GexSiyOz, a high dielectric constant dielectric film, a combination thereof, or a stacked film obtained by stacking the above materials. The high dielectric constant dielectric film may include, but is not limited to, one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The gate insulating film 175 may be formed using, for example, heat treatment, chemical treatment, atomic layer deposition (ALD), chemical vapor deposition (CVD), or the like. If the gate insulating film 175 includes a high dielectric constant dielectric material, a barrier film may be further formed between the gate insulating film 175 and the gate electrode 180. The barrier film may include, for example, at least one of titanium nitride (TiN), tantalum nitride (TaN), and combinations thereof.

The gate electrode 180 may include, for example, one or more of polycrystalline silicon (poly Si), amorphous silicon (a-Si), titanium (Ti), titanium nitride (TiN), tantalum nitride (TaN), aluminum (Al), and combinations thereof. Polycrystalline silicon (poly Si) may be formed, for example, using the chemical vapor deposition, and amorphous silicon may be formed, for example, using the sputtering, the chemical vapor deposition, the plasma deposition, and the like, but the inventive concepts are not limited thereto.

The first spacer film 162 and the second spacer film 164 may include, for example, a silicon nitride film, a silicon oxynitride film, a silicon oxide film, and/or a silicon carboxynitride film (SiOCN). The first spacer film 162 and the second spacer film 164 may be formed, for example, using a chemical vapor deposition or the like. The first spacer film 162 and the second spacer film 164 are illustrated as being formed of a single layer, but the inventive concepts not limited thereto, and they may be formed of multiple layers.

The gate hard mask 170 may include, for example, a nitride film, an oxide film, and a combination thereof. The gate hard mask 170 may be formed, for example, using a chemical vapor deposition or the like.

Unlike the case illustrated in FIG. 1, the gate hard mask 170 may not be formed on the gate electrode 180.

A first impurity region 132 and a second impurity region 134 may be formed on both sides of the gate electrode 180. A first low-concentration impurity region (lightly doped dopant region) 136 may be formed between the first impurity region 132 and the gate electrode 180. A second low-concentration impurity region 138 may be formed between the second impurity region 134 and the gate electrode 180.

The first low-concentration impurity region 136, the second low-concentration impurity region 138, the first impurity region 132 and/or the second impurity region 134 may contain impurities.

When the transistor formed on the substrate 110 is a pFET, the conductivity type of the impurities contained in the first low-concentration impurity region 136, the second low-concentration impurity region 138, the first impurity region 132 and/or the second impurity region 134 may be a p-type impurity. The p-type impurity may be, for example, boron (B) or the like.

The impurities contained in the first low-concentration impurity region 136, the second low-concentration impurity region 138, the first impurity region 132 and/or the second impurity region 134 in which the transistor formed on the substrate 110 is an nFET may be n-type impurities. The n-type impurities may be, for example, phosphorus (P), arsenic (As) or antimony (Sb) or the like.

The gate electrode 180 may be formed on the substrate 110, and exposed silicon regions may be provided on both sides of the gate electrode 180. The exposed silicon regions provided on both sides of the gate electrode 180 may include a first low-concentration impurity region 136, a second low-concentration impurity region 138, a first impurity region 132, and/or a second impurity region 134.

In the semiconductor device and the method for fabricating the semiconductor device according to some example embodiments, the silicon regions provided on both sides of the gate electrode 180 may be a part of the substrate 110.

The first metal silicide film 102 and/or the second metal silicide film 104 may be formed on the first low-concentration impurity region 136, the second low-concentration impurity region 138, the first impurity region 132 and/or the second impurity region 134 which are exposed silicon regions.

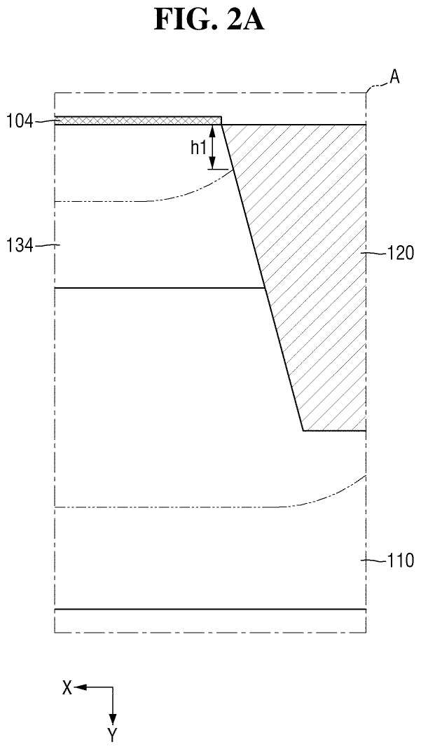

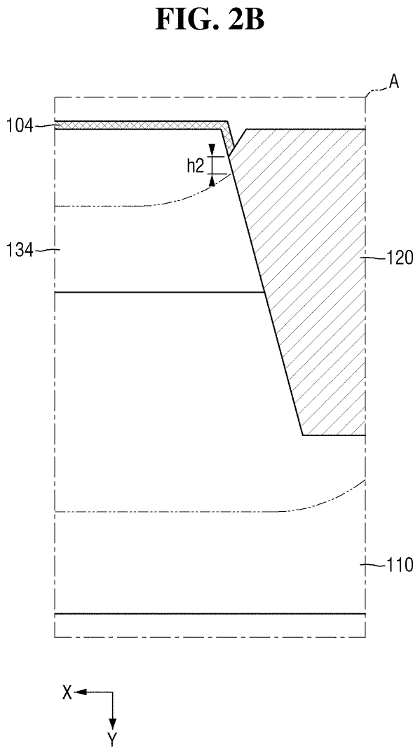

A voltage may be applied to the second low-concentration impurity region 138 and/or the second impurity region 134 through the second metal silicide film 104 to drive the semiconductor device 100. A junction leakage current may be generated when a reverse voltage is applied to a pn junction formed between the second low-concentration impurity region 138 and the second impurity region 134 and the substrate 110. Some specific examples in which the junction leakage current may be generated will be explained through FIGS. 2A and 2B which are enlarged views of a junction A in which the second impurity region 134 meets the second element isolation film 120.

FIG. 2A is an enlarged view of the junction A of the semiconductor device of FIG. 1.

Referring to FIG. 2A, a pn junction may be formed between the second impurity region 134 and the substrate 110. The junction surface between the second impurity region 134 and the substrate 110 is illustrated as being linear in the x direction for convenience, but is not limited thereto.

The second impurity region 134 may be generated by implanting a first impurity of a first concentration. The first concentration of the first impurity may decrease from an upper part of the substrate 110 into which the first impurity is implanted toward a lower part (+y direction) of the substrate 110. A depletion region (indicated by a two-dot chain line) formed by the pn junction may be wider as the concentration is low. Thus, the depletion region in the second impurity region 134 may approach the upper part of the substrate 110. Further, a reverse voltage is formed in the pn junction by the voltage applied to the second impurity region 134 through the second metal silicide film 104, and the depletion region may be widened. Therefore, the depletion region formed in the second impurity region 134 may approach the upper part of the substrate 110 by a distance of h1 in the y direction.

When the depletion region formed in the second impurity region 134 approaches the upper part of the substrate 110, the junction leakage current may be generated by the voltage applied to the second impurity region 134 through the second metal silicide film 104.

Therefore, by increasing the first concentration of the second impurity region 134, it is possible to alleviate the widening of the depletion region and to reduce or suppress the generation of junction leak current.

FIG. 2B is an enlarged view of a junction A of the semiconductor device of FIG. 1. Referring to FIG. 2B, the pn junction may be formed between the second impurity region 134 and the substrate 110. The junction surface between the second impurity region 134 and the substrate 110 is illustrated as being linear in the x direction for convenience, but is not limited thereto. For brevity of description, the following will mainly explain differences from the depletion region widening discussed with reference to FIG. 2A.

In addition to the low first concentration of the first impurity forming the second impurity region 134 and the reverse voltage applied to the second impurity region 134, the depletion region of the second impurity region 134 may approach the upper part of the substrate 110.

The second element isolation film 120 may sink in the +y direction at the portion in which the second metal silicide film 104, the second impurity region 134, and/or the second element isolation film 120 meet together. That is, unlike the second element isolation film 120 of FIG. 2A, the second metal silicide film 104 may move in the +y direction along the second impurity region 134.

The second metal silicide film 104 may approach the depletion region formed in the second impurity region 134 by a distance h2 in the +y direction. This may be a shorter distance than h1 of FIG. 2a. When the depletion region in the second impurity region 134 approaches the second metal silicide film 104, the junction leakage current may be more easily formed by the voltage to be applied to the second impurity region 134 through the second metal silicide film 104.

Therefore, by increasing the first concentration of the second impurity region 134, it is possible to alleviate the widening of the depletion region and to reduce or suppress the generation of junction leak current. Hereinafter, a semiconductor device and a method for fabricating the semiconductor device according to some example embodiments, in which the first concentration of the second impurity region 134 is increased, will be described.

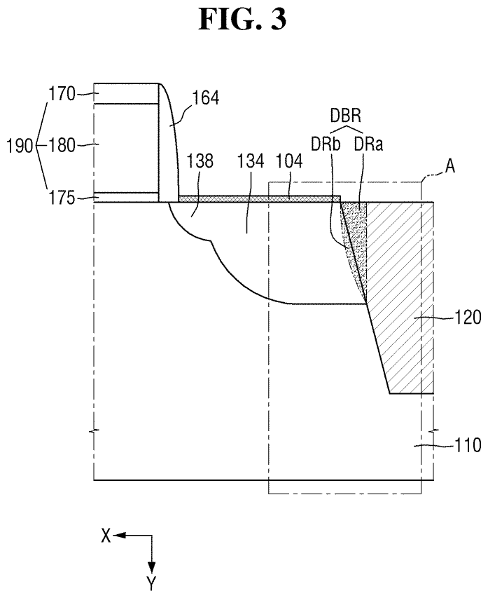

FIG. 3 is an example diagram of the semiconductor device according to some example embodiments of the present inventive concepts.

The description of the same configuration as FIG. 1 will be omitted, and differences will be mainly described.

Referring to FIG. 3, a depletion buffer region (DBR) may be formed along at least a part of the first and/or second element isolation films 119 and 120. The depletion buffer region (DBR) may include a diffusion region DRa and/or a diffused region DRb.

The depletion buffer region (DBR) may be formed of a second impurity of a second concentration. The second impurity may be the same conductivity type as the first impurity of the first concentration that forms the first and/or second impurity regions 132 and 134.

For example, if the transistor formed on the substrate 110 is a pFET, the conductivity type of the first impurity contained in the first and/or second impurity regions 132 and 134 may be a p-type impurity, and the second impurity may also be the p-type impurity. The p-type impurity may be, for example, boron (B) or the like. On the other hand, when the transistor formed on the substrate 110 is an nFET, the conductivity type of the first impurity contained in the second impurity region 134 may be an n-type impurity, and the second impurity may also be the n-type impurity. The n-type impurity may be, for example, phosphorus (P), arsenic (As) or antimony (Sb) or the like.

The first and second impurities may be the same material, without being limited to a case where the conductivity types of the first and second impurities are the same.

In order to increase the first concentration of the first impurity forming the first and/or second impurity regions 132 and 134, the second concentration of the second impurity forming the depletion buffer region (DBR) may be higher than the first concentration. Therefore, the second impurity may diffuse from the diffusion region DRa to the diffused region DRb. A heat treatment process may be performed for diffusion. The diffused region DRb, which is a region diffused from the diffusion region DRa, is not limited thereto, and may be further widened by +x/or +y from the surface on which the first element isolation film 119 and the first impurity region 132 meet together and/or from the surface on which the second element isolation film 120 and the second impurity region 134 meet together.

By increasing the first concentration of the second impurity region 134 through the depletion buffer region (DBR) according to some example embodiments, it is possible to relieve widening of the depletion region in the first and/or second impurity regions 132 and 134 and to reduce or suppress the generation of junction leak current.

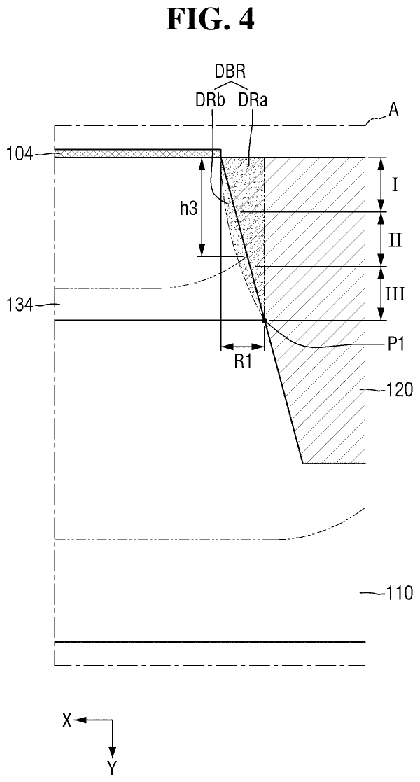

FIG. 4 is an enlarged view of a junction A of the semiconductor device according to some example embodiments of the present inventive concepts.

The same reference numerals are used to denote the same elements as in FIG. 3, and thus repeated descriptions thereof are omitted.

Referring to FIG. 4, the diffusion region DRa of the depletion buffer region (DBR) may include a first region I, a second region II, and/or a third region III. The first region I, the second region II, and/or the third region III may have a second impurity of a second concentration, a third impurity of a third concentration, and a fourth impurity of a fourth concentration, respectively.

The conductivity types of the second to fourth impurities may be the same as the conductivity type of the first impurity forming the second impurity region 134. In addition, the second to fourth impurities may be the same material as the first impurity, without being limited thereto.

In order to increase the first concentration of the first impurity forming the second impurity region 134, the second to fourth concentrations of the second impurity forming the depletion buffer region (DBR) may be higher than the first concentration. Therefore, the second impurity may be diffused from the diffusion region DRa to the diffused region DRb. A second diffusion region DRa2, which is a region diffused from the first diffusion region DRa1, is not limited thereto, and may be further widened by +x and/or +y from the surface on which the second element isolation film 120 and the second impurity region 134 meet together.

By increasing the first concentration of the second impurity region 134 through the depletion buffer region (DBR) according to some example embodiments, it is possible to relieve widening of the depletion region in the second impurity region 134 and to reduce or suppress the generation of junction leak current. That is, since a distance h3 in the +y direction at which the upper part of the substrate 110 meets the depletion region in the second impurity region 134 becomes longer than h1 and h2 of FIGS. 2A and 2B, generation of the junction leak current may be reduced or suppressed.

In some example embodiments, the number of divided regions I, II and/or III in the diffusion regions DRa is not limited thereto.

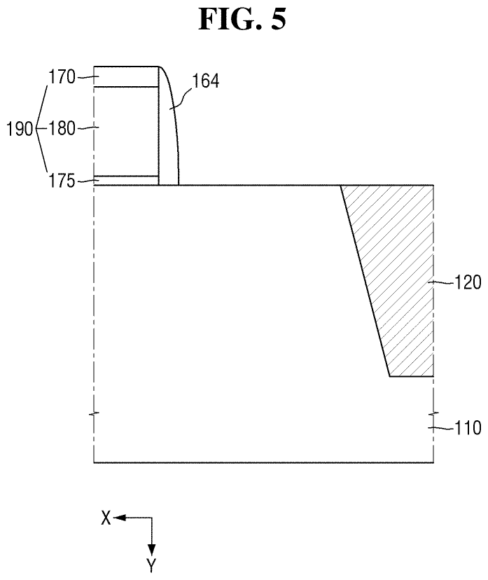

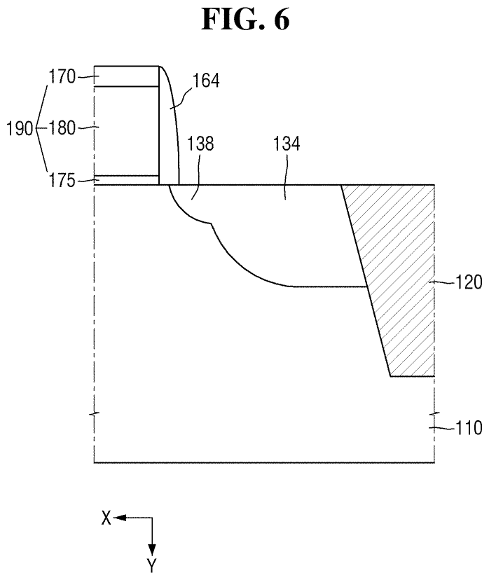

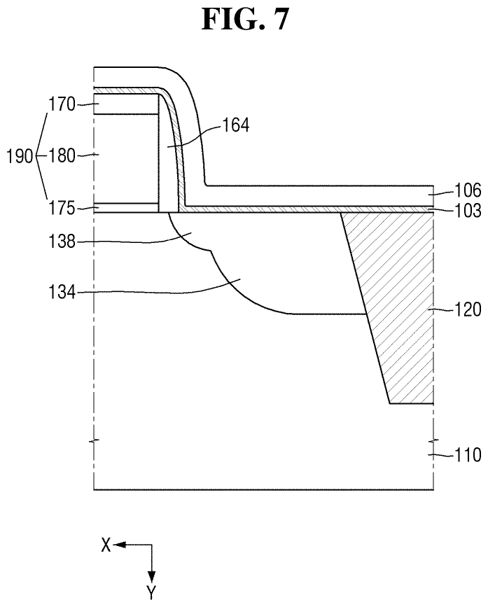

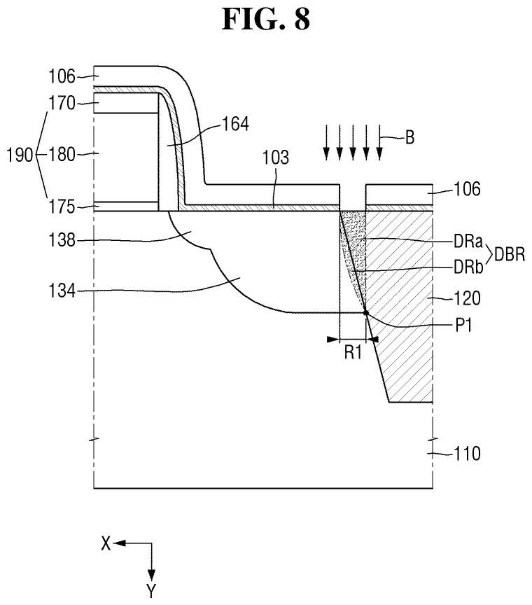

FIG. 5 is an intermediate stage view illustrating a method for fabricating the semiconductor device of FIG. 3 according to some example embodiments of the present inventive concepts. FIG. 6 is an intermediate stage view illustrating the method for fabricating the semiconductor device of FIG. 3 according to some example embodiments of the present inventive concepts. FIG. 7 is an intermediate stage view illustrating the method for fabricating the semiconductor device of FIG. 3 according to some example embodiments of the present inventive concepts. FIG. 8 is an intermediate stage view illustrating the method for fabricating the semiconductor device of FIG. 3 according to some example embodiments of the present inventive concepts.

Referring to FIG. 5, a gate insulating film 175, a gate electrode 180, and/or a gate hard mask 170 sequentially stacked on the substrate 110 of the semiconductor device may be formed. A second spacer film 164 may be formed on the side walls of the gate electrode 180. More specifically, the second element isolation film 120 may be formed in the substrate 110. The second element isolation film 120 may be formed as a shallow trench isolation (STI) structure, which has excellent element isolation characteristics and a small occupied area and is advantageous for high integration, but is not limited thereto.

The second element isolation film 120 may include, for example, one of silicon oxide, silicon oxynitride, silicon nitride, and combinations thereof.

Thereafter, a spacer film which covers the gate stack 190 may be formed on the substrate 110. The spacer film may be directionally etched to form the second spacer film 164 on the side walls of the gate stack 190.

The gate electrode 180 may include, for example, one of polycrystalline silicon (poly Si), amorphous silicon (a-Si), titanium (Ti), titanium nitride (TiN), tantalum nitride (TaN), aluminum (Al), and combinations thereof. The polycrystalline silicon (poly Si) may be formed, for example, using the chemical vapor deposition, and the amorphous silicon may be formed, for example, using the sputtering, the chemical vapor deposition, the plasma deposition, and the like, but is not limited thereto.

The second spacer film 164 may include, for example, a silicon nitride film, a silicon oxynitride film, a silicon oxide film, a silicon carboxynitride film (SiOCN), and combinations thereof. The second spacer film 164 may be formed, for example, using the chemical vapor deposition or the like. The second spacer film 164 is illustrated as being formed of a single layer, but may be formed of multiple layers without being limited thereto.

The gate hard mask 170 may include, for example, a nitride film, an oxide film, and combinations thereof. The gate hard mask 170 may be formed, for example, using the chemical vapor deposition or the like.

Unlike the case illustrated in FIG. 5, the gate hard mask 170 may not be formed on the gate electrode 180.

Referring to FIG. 6, a second impurity region 134 may be formed on one side of the gate electrode 180. A second low-concentration impurity region 138 may be formed between the second impurity region 134 and the gate electrode 180.

The second low-concentration impurity region 138 and/or the second impurity region 134 may include impurities.

When the transistor formed on the substrate 110 is a pFET, the conductivity type of the impurities contained in the second low-concentration impurity region 138 and/or the second impurity region 134 may be a p-type impurity. The p-type impurity may be, for example, boron (B) or the like.

When the transistor formed on the substrate 110 is an nFET, the impurities contained in the second low-concentration impurity region 138 and/or the second impurity region 134 may be n-type impurities. The n-type impurities may be, for example, phosphorus (P), arsenic (As) antimony (Sb) or the like.

A gate electrode 180 may be formed on the substrate 110. Exposed silicon regions may be provided on both sides of the gate electrode 180. The exposed silicon regions provided on both sides of the gate electrode 180 may include a second low-concentration impurity region 138 and/or a second impurity region 134.

In the semiconductor device and the method for fabricating the semiconductor device according to some example embodiments, the silicon regions provided on both sides of the gate electrode 180 may be a part of the substrate 110.

Referring to FIG. 7, a free metal silicide film 103 may be formed on the second low-concentration impurity region 138, the second impurity region 134, the second element isolation film 120, the second spacer film 164, and/or the gate stack 190 which are the silicon regions. A passivation film 106 may be formed on the free metal silicide film 103.

The passivation film 106 may include, but is not limited to, one or more of silicon nitride (SiNx), silicon oxide (SiO2) and/or silicon oxynitride (SiON) containing hydrogen. Further, the passivation film 106 may be deposited on the free metal silicide film 103 through a PECVD (Plasma Enhanced Chemical Vapor Deposition), but is not limited thereto.

Referring to FIGS. 3 and 8, the region R1 of the passivation film 106 and the free metal silicide film 103 may be removed through exposure and development, using a photoresist. Thereafter, a second impurity may be implanted through a process B to form the depletion buffer region (DBR). The process B may be, for example, but is not limited to, one of an ion implantation process or a diffusion process. Hereinafter, the process B will be described as an ion implantation process.

The passivation film 106 may act as a mask for the second impurity implanted by the process B. Therefore, the second impurity implanted by the process B may be implanted into the region R1 of the second element isolation film 120 opened by etching.

If the amount of dose implanted by the process B remains the same, as the energy implanted is raised, the depth of the depletion buffer region (DBR) may be further deepened in the +y direction. If the level of implantation energy in the process B remains the same, as the amount of dose implanted is raised, the concentration of the second impurity generated in the depletion buffer region (DBR) may increase. Therefore, as illustrated in FIG. 4, the regions in which the concentration of the second impurity is different may be formed in the first diffusion region DRa1.

Thereafter, the passivation film 106 is removed, the free metal silicide film 103 is patterned, a heat treatment process is performed, and/or the second metal silicide film 104 may be formed on the second low-concentration impurity region 138 and/or the second impurity region 134 which are exposed silicon regions.

More specifically, except for the free metal silicide film 103 on the second low-concentration impurity region 138 and the second impurity region 134, the profile of the gate stack 190, and the free metal silicide film 103 on the second spacer film 164 and the second element isolation film 120 may be patterned and removed. Therefore, the semiconductor device of FIG. 3 according to some example embodiments may be formed.

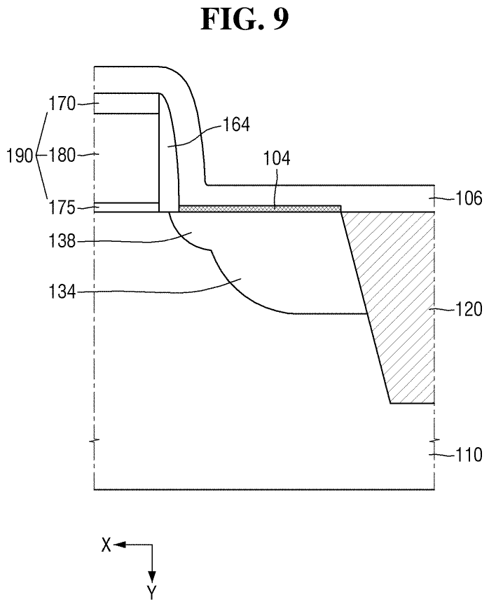

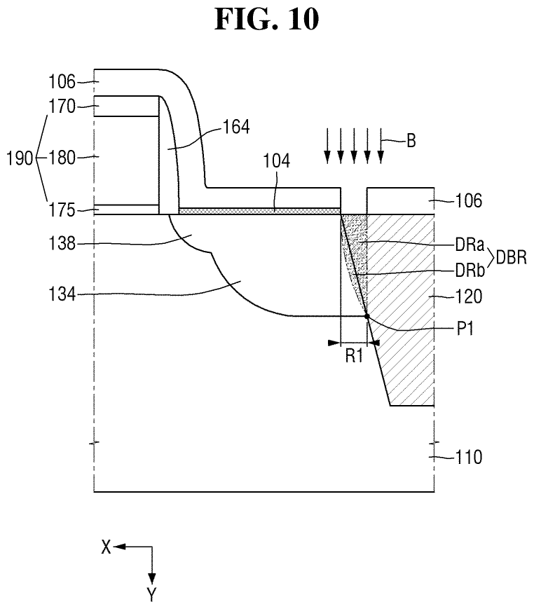

FIG. 9 is an intermediate stage view illustrating the method for fabricating the semiconductor device of FIG. 3 according to some example embodiments of the present inventive concepts. FIG. 10 is an intermediate stage view illustrating the method for fabricating the semiconductor device of FIG. 3 according to some example embodiments of the present inventive concepts.

The stages before the intermediate stage of the method for fabricating the semiconductor device of FIG. 9 are the same as the fabricating method described in FIGS. 5 and 6.

Referring to FIG. 9, unlike FIG. 7, after the second metal silicide film 104 is formed on the second low-concentration impurity region 138 and/or the second impurity region 134 which are silicon regions that have been exposed in advance, the passivation film 106 may be formed. The passivation film 106 may be formed on the gate stack 190, the second metal silicide film 104, and/or the second element isolation film 120.

The passivation film 106 may include, but is not limited to, one or more of silicon nitride (SiNx), silicon oxide (SiO2) and silicon oxynitride (SiON) containing hydrogen. Further, the passivation film 106 may be deposited on the free metal silicide film 103 through a PECVD (Plasma Enhanced Chemical Vapor Deposition), but is not limited thereto.

Referring to FIGS. 3 and 10, a region R1 of the passivation film 106 and the second metal silicide film 104 may be removed through exposure and development, using a photoresist. Thereafter, a second impurity may be implanted through the process B to form the depletion buffer region (DBR). The process B may be, for example, but is not limited thereto, one of an ion implantation process or a diffusion process. Hereinafter, the process B will be described as an ion implantation process.

The passivation film 106 may act as a mask for the second impurity implanted by the process B. Therefore, the second impurity implanted by the process B may be implanted into the region R1 of the second element isolation film 120 opened by etching.

If the amount of dose implanted by the process B remains same, as the energy be implanted is raised, the depth of the depletion buffer region (DBR) may be further deepened in the +y direction. If the level of implantation energy in the process B remains the same, as the amount of dose implanted is raised, the concentration of the second impurity generated in the depletion buffer region (DBR) will increase. Therefore, as illustrated in FIG. 4, the region in which the concentration of the second impurity is different may be formed in the diffusion region DRa.

Thereafter, the passivation film 106 may be removed to form the semiconductor device of FIG. 3 according to some example embodiments.

Hereinafter, unlike the method for fabricating the semiconductor device of FIGS. 5 to 10, a method for fabricating the semiconductor device, according to some example embodiments, in which the depletion diffusion region is formed in advance in the formation process of the element isolation film, will be described. That is, the method for fabricating the semiconductor device, according to some example embodiments, in which the depletion diffusion region is formed in advance before the gate stack, the spacer, the first and second low-concentration impurity regions, and/or the first and second impurity regions are formed, will be described.

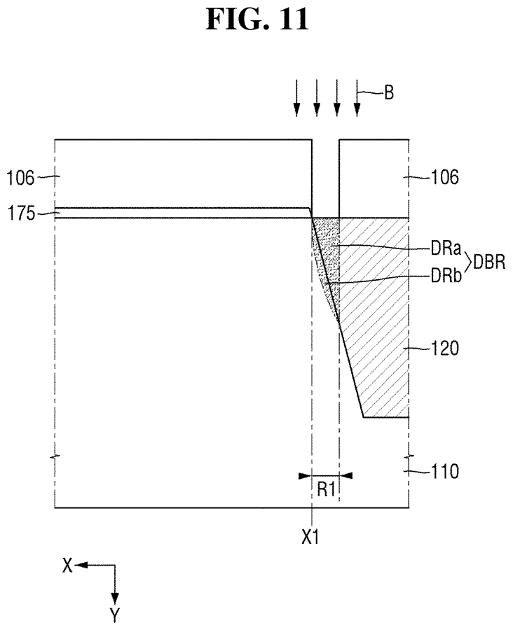

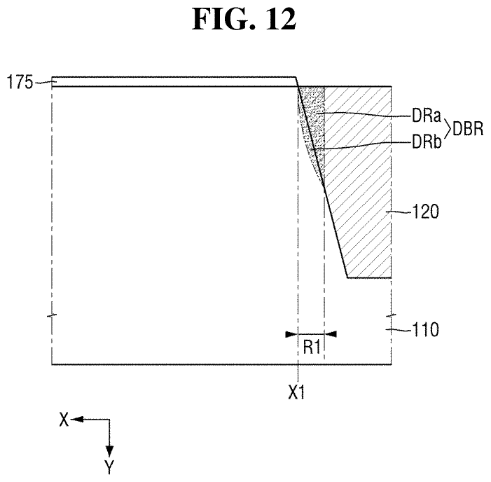

FIG. 11 is an intermediate stage view illustrating the method for fabricating the semiconductor device of FIG. 3 according to some example embodiments of the present inventive concepts. FIG. 12 is an intermediate stage view illustrating the method for fabricating the semiconductor device of FIG. 3 according to some example embodiments of the present inventive concepts.

Referring to FIG. 11, after a gate insulating film 175, a nitride film and/or a photoresist are first formed on the substrate 110, the photoresist is exposed and developed to form a trench, a buried oxide film is formed in the trench to form the second element isolation film 120, the passivation film 106 is formed after removing the nitride film, and/or the region R1 may be etched through the exposure and development, using a photoresist.

Thereafter, a second impurity may be implanted through the process B to form the depletion buffer region (DBR). The process B may be, for example, but is not limited to, one of an ion implantation process or a diffusion process. Hereinafter, the process B will be described as an ion implantation process.

The passivation film 106 may act as a mask for the second impurity implanted in the process B. Therefore, the second impurity implanted in the process B may be implanted into the region R1 of the second element isolation film 120 opened by etching.

If the amount of dose implanted by process B remains the same, as the energy implanted is raised, the depth of the depletion buffer region (DBR) will be further deepened in the +y direction. If the level of implantation energy in the process B remains the same, as the amount of dose implanted is raised, the concentration of the second impurity generated in the depletion buffer region (DBR) may increase. Therefore, as illustrated in FIG. 4, the region in which the concentration of the second impurity is different may be formed in the diffusion region DRa.

Referring to FIGS. 3 and 12, a depletion buffer region (DBR) may be formed along at least a part of the side walls of the second element isolation film 120. The passivation film 106 may be removed, and only the gate insulating film 175 may remain on the substrate 110.

The semiconductor device according to some example embodiments of FIG. 3 can be formed via the method for fabricating the semiconductor device according to some example embodiments of FIGS. 5 to 6 in a state in which the depletion buffer region (DBR) is formed.

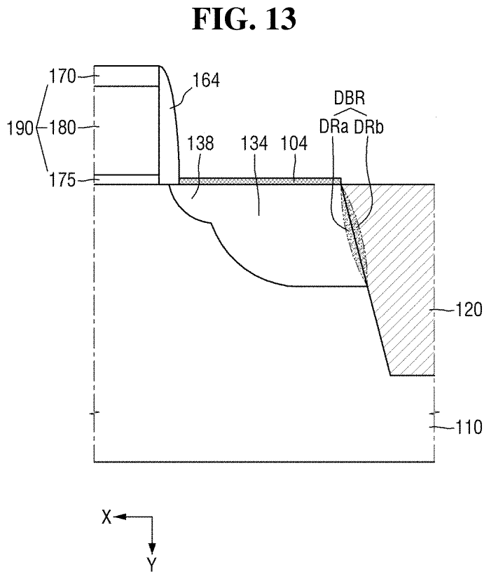

FIG. 13 is an example diagram of the semiconductor device according to some example embodiments of the present inventive concepts.

Compared to the semiconductor device according to some example embodiments of FIG. 3, there is a difference in that the shape of the depletion buffer region (DBR) is elliptical. This is caused by a different method for fabricating the semiconductor device according to some example embodiments of FIG. 13 from the method for fabricating the semiconductor device of FIG. 3 according to some example embodiments. In some example embodiments, the shape of the depletion buffer region (DBR) is not limited to an elliptical shape.

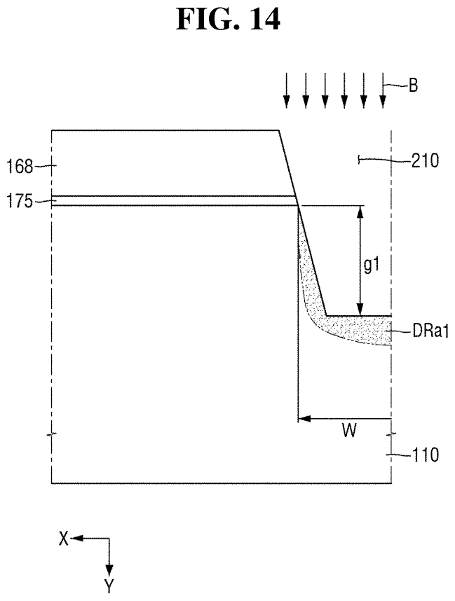

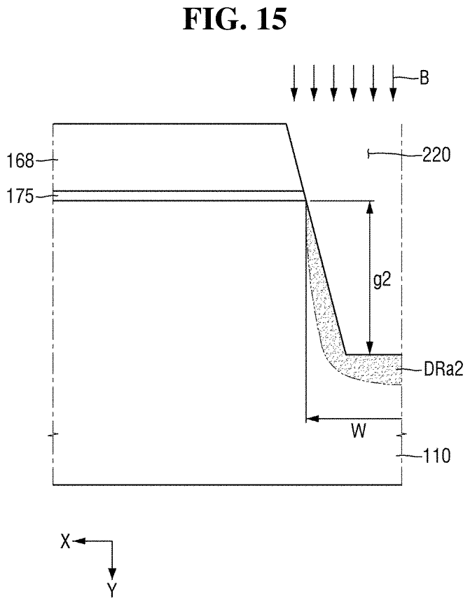

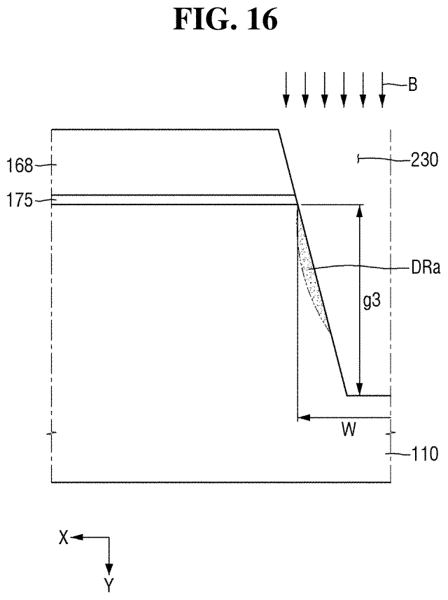

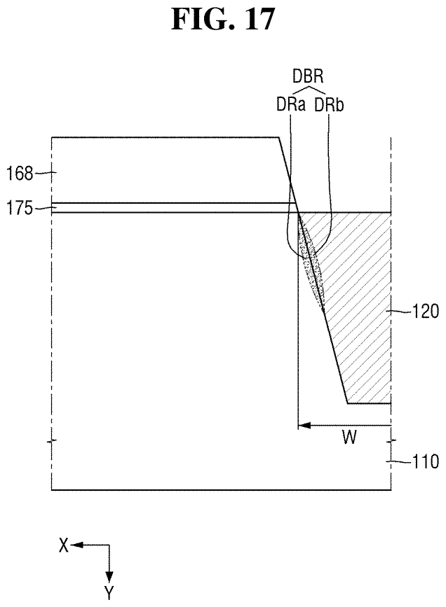

FIG. 14 is an intermediate stage view illustrating the method for fabricating the semiconductor device of FIG. 13 according to some example embodiments of the present inventive concepts. FIG. 15 is an intermediate stage view illustrating the method for fabricating the semiconductor device of FIG. 13 according to some example embodiments of the present inventive concepts. FIG. 16 is an intermediate stage view illustrating the method for fabricating the semiconductor device of FIG. 13 according to some example embodiments of the present inventive concepts. FIG. 17 is an intermediate stage view illustrating the method for fabricating the semiconductor device of FIG. 13 according to some example embodiments of the present inventive concepts.

Referring to FIG. 14, a gate insulating film 175 and a nitride film 168 are sequentially stacked on the substrate 110. After forming a photoresist on the nitride film 168, the photoresist is exposed and developed to remove the photoresist of the first trench 210 region. The substrate 110, the gate insulating film 175, and/or the nitride film 168 may be etched to form a first trench 210. The first trench 210 may be formed using a dry etching process such as reactive ion etching (RIE), but is not limited thereto.

Thereafter, a second impurity may be implanted through the process B to form the depletion buffer region. Therefore, the first diffusion region DRa1 may be formed in the substrate 110 along the side walls of the first trench 210. The process B may be, for example, but is not limited to, one of an ion implantation process or a diffusion process. Hereinafter, the process B will be described as an ion implantation process.

A depth of the first trench 210 may have a length of g1 in the +y direction, and/or a width thereof may have a dimension w along the x direction.

Referring to FIG. 15, the substrate 110, the gate insulating film 175 and/or the nitride film 168 may be etched to form a second trench 220. The second trench 220 may be formed, but is not limited to, using a dry etching process such as reactive ion etching (RIE). The width of the second trench 220 may be w, and the depth g2 may be deeper than g1. Thereafter, a second impurity may be implanted through the process B to form the depletion buffer region. Therefore, the second diffusion region DRa2 may be formed in the substrate 110 along the side wall of the second trench 220.

Referring to FIG. 16, the substrate 110, the gate insulating film 175 and/or the nitride film 168 may be etched to form a third trench 230. The third trench 230 may be formed, but is not limited to, using a dry etching process such as reactive ion etching (RIE). The width of the third trench 230 may be w, and the depth g3 may be deeper than g2.

The number of repetitions of forming the trench and implanting the impurity according to some example embodiments is not limited thereto.

As the substrate 110 below the second trench 220 etched in the etching process, a part of the second diffusion region DRa2 may be etched. A part of the second diffusion region DRa2 may be etched to form a diffusion region DRa in the substrate 110 along at least a part of the third trench 230.

Referring to FIGS. 13 and 17, an oxide film may be deposited on the third trench 230 to form a second element isolation film 120. The oxide film may be deposited, but is not limited thereto, through chemical vapor deposition (CVD).

The second impurity of the diffusion region DRa may be diffused into the second element isolation film 120 to form a diffused region DRb, and the diffusion region DRa and the diffused region DRb may form the depletion buffer region (DBR).

Thereafter, the nitride film 168 is removed in a state in which the depletion buffer region (DBR) is formed, and the semiconductor device according to some example embodiments of the inventive concepts may be formed via the method for fabricating the semiconductor device according to some example embodiments of FIGS. 5 to 6.

Those skilled in the art will appreciate that many variations and modifications may be made to the example embodiments without substantially departing from the principles of the present inventive concepts. Therefore, the disclosed example embodiments of the inventive concepts are used in a generic and descriptive sense only and not for purposes of limitation.

While the present inventive concepts have been particularly shown and described with reference to example embodiments thereof, it will be understood by those of ordinary skill in the art that various changes in form and details may be made therein without departing from the spirit and scope of the present inventive concepts as defined by the following claims. It is therefore desired that the example embodiments be considered in all respects as illustrative and not restrictive, reference being made to the appended claims rather than the foregoing description to indicate the scope of the inventive concepts.

What is claimed is:

1. A semiconductor device comprising:
a substrate;
a gate electrode on the substrate;
an element isolation film in the substrate and spaced apart from the gate electrode;
an impurity region between the element isolation film and the gate electrode, the impurity region including a first impurity of a first concentration; and
a depletion buffer region on at least a part of side walls of the element isolation film, the depletion buffer region including a second impurity of a second concentration higher than the first concentration, a conductivity type of the second impurity being the same as a conductivity type of the first impurity.

2. The semiconductor device of claim 1, wherein the depletion buffer region is not on a bottom surface of the element isolation film.

3. The semiconductor device of claim 1, wherein the first impurity is the same as the second impurity.

4. The semiconductor device of claim 1, wherein the element isolation film includes a diffusion region including the second impurity of a third concentration higher than the second concentration.

5. The semiconductor device of claim 4, wherein the diffusion region is on at least a part of the side walls of the element isolation film.

6. The semiconductor device of claim 4, wherein the element isolation film includes a lower part, and an upper part on the lower part, and
the diffusion region is in the upper part.

7. The semiconductor device of claim 1, wherein,
the element isolation film includes a diffusion region,
the diffusion region includes the second impurity having a third concentration lower than the second concentration, and
the diffusion region is on at least a part of the side walls of the element isolation film.

8. A semiconductor device comprising:
a substrate;
first element isolation films in the substrate;
a gate electrode on the substrate between the first element isolation film and the second element isolation film;
a low-concentration impurity region between the first element isolation film and the gate electrode, the low-concentration impurity region including a first impurity of a first concentration;
a impurity region between the first element isolation film and the gate electrode, the impurity region including a second impurity of a second concentration; and
a depletion buffer region on at least a part of side walls of the first element isolation film and including a third impurity of a third concentration higher than the second concentration, a conductivity type of the third impurity being the same as the conductivity type of the second impurity.

9. The semiconductor device of claim 8, wherein the depletion buffer region is not on a bottom surface of the second element isolation film.

10. The semiconductor device of claim 8, wherein the third impurity is the same as the second impurity.

11. The semiconductor device of claim 8, wherein the first element isolation film includes a diffusion region including the third impurity of a fourth concentration higher than the third concentration.

12. The semiconductor device of claim 11, wherein the diffusion region is on at least a part of the side walls of the first element isolation film.

13. The semiconductor device of claim 11, wherein the first element isolation film includes a lower part, and an upper part on the lower part, and
the diffusion region is in the upper part.

14. The semiconductor device of claim 8, wherein,
the first element isolation film includes a diffusion region,
the diffusion region includes the third impurity of a fourth concentration lower than the third concentration, and
the diffusion region is on at least a part of the side walls of the first element isolation film.

15. A semiconductor device comprising:
a substrate;
a gate electrode on the substrate;
an element isolation film in the substrate and spaced apart from the gate electrode;
a first impurity region including a first impurity of a first concentration between the element isolation film and the gate electrode;
a second impurity region including a second impurity of a second concentration higher than the first concentration, between the first impurity region and the element isolation film, a conductivity type of the second impurity being the same as the conductivity type of the first impurity; and
a depletion buffer region on at least a part of side walls of the element isolation film and including a third impurity of a third concentration higher than the second concentration, a conductivity type of the third impurity being the same as that of the second impurity.

16. The semiconductor device of claim 15, wherein the depletion buffer region is not on a bottom surface of the element isolation film.

17. The semiconductor device of claim 15, wherein the element isolation film includes a diffusion region including a fourth impurity of a fourth concentration higher than the third concentration.

18. The semiconductor device of claim 17, wherein the diffusion region is on at least a part of the side walls of the element isolation film.

19. The semiconductor device of claim 17, wherein the element isolation film includes a lower part, and an upper part on the lower part, and
the diffusion region is in the upper part.

20. The semiconductor device of claim 15, wherein,
the element isolation film includes a diffusion region,
the diffusion region includes a fourth impurity of a fourth concentration lower than the third concentration, and
the diffusion region is on at least a part of the side walls of the element isolation film.
